(19) United States
(12) Patent Application Publication
(10) Pub. No.: US 2003/0186551 A1
(43) Pub. Date: Oct. 2, 2003

(54) Integration scheme for metal gap fill with HDP and fixed abrasive CMP

(75) Inventors: Peter Wrschka, Wappingers Falls, NY (US); Werner Robl, Poughkeepsie, NY (US); Thomas Goebel, Fishkill, NY (US)

Correspondence Address: SLATER & MATSIL, L.L.P., 17950 PRESTON RD, SUITE 1000, DALLAS, TX, 75252-5793, US

(73) Assignee: Infineon Technologies North America Corp.

(21) Appl. No.: 10/108,358

(22) Filed: Mar. 29, 2002

(51) Int. Cl. H01L 21/4763

(52) U.S. Cl. 438/690

(57) ABSTRACT

In a method of planarizing a semiconductor wafer, the improvement comprising polishing above metal interconnect lines to uniformly polish the topography of the wafer to a predetermined endpoint on the wafer sufficiently close above the metal interconnect lines, yet far enough away from the lines to prevent damage to the lines, comprising:

a) filling gaps between metal interconnect lines of an inter metal dielectric in a wafer being formed, by depositing HDP fill on top of the metal interconnects, between the metal interconnects, and on the surface of a substrate or dielectric layer between the metal interconnects to create an HDP overfill so that the level of the bottom of roofs of the overfill above the metal lines is the endpoint upon use of FAP to remove topography;

d) contacting the surface of HDP overfill of the processed semiconductor wafer from step a) with a fixed abrasive polishing pad; and

e) relatively moving the wafer and the fixed abrasive polishing pad to affect a polishing rate sufficient to reach the predetermined endpoint and uniformly planar surface on the wafer sufficiently close above the metal interconnect lines and yet far enough away from the lines to prevent damage to the lines.

### BACKGROUND OF THE INVENTION

1. Field of Invention

The invention relates to an integration scheme for metal gap fill with high density plasma (HDP) only and Fixed Abrasive CMP (chemical mechanical polishing (FAP) to enable polishing of the topography only in the absence of a silane oxide cap layer, when modifying the exposed surface of a semiconductor wafer.

2. Description of the Related Art

In a process integration scheme for preparing a semiconductor wafer, the wafer typically undergoes many processing steps, and these processing steps include deposition, patterning, and etching steps. At each step during the manufacturing process, it is useful to attain a pre-determined level of uniformity and/or planarization. Further, it is also useful to minimize any surface defects in the wafer, such as scratches and pits, since these surface defects will affect the performance of the ultimate patterned semiconductor wafer.

One well known method for reducing surface irregularities during the manufacture of semiconductor wafers is to treat the wafer surface with a slurry that contains a plurality of loose abrasive particles using a polishing pad.

U.S. Pat. No. 6,007,407 disclose a method of modifying an exposed surface of a semiconductor wafer comprising:

(a) contacting the surface with an abrasive construction comprising a three-dimensional, fixed abrasive element having raised portions and recess portions, wherein the raised portions comprises abrasive particles and binder; at least one resilient element coextensive with the fixed abrasive element; and at least one rigid element coextensive with and interposed between the resilient element and the fixed abrasive element; wherein the rigid element has a Young's Modulus greater than that of the resilient element; and

(b) relatively moving the wafer and the abrasive construction to modify the surface of the wafer.

A method of modifying a processed semiconductor wafer containing topographical features is disclosed in U.S. Pat. No. 5,958,794. The method entails:

(a) contacting an exposed surface of the semiconductor wafer with a three-dimensional, textured, fixed abrasive article comprising a plurality of abrasive particles and a binder arranged in the form of a pattern; and

(b) relatively moving the wafer and the fixed abrasive article in the presence of a liquid medium to chemically and mechanically modify the surface of the wafer.

U.S. Pat. No. 6,325,702 B2 disclose a method for chemical-mechanical-polishing (CMP) to selectively remove a first material over a second material, wherein said first material and said second material form part of a substrate assembly. The method comprises:

selecting a pad configured to remove the first material more rapidly than the second material, the pad being formed at least in part of an intrinsically non-porous material with respect to CMP solution particles to be used therewith, the pad formed with spaced-apart contact portions;

the contact portions separated by at least one non-contact portion, the contact portions formed of the intrinsically non-porous material to provide a surface to contact the substrate assembly during CMP, the contact portions spaced-apart to provide a duty cycle, the duty cycle determined at least in part by:

selecting a contact width for the contact portions based at least in part on the CMP solution, the first material, and the second material;

selecting a non-contact width associated with spacing of the contact portions, the non-contact width selected based at least in part on the CMP solution, the first material, and the second material; placing the pad on a chemical-mechanical-polisher platform; providing the CMP solution to the pad; and polishing the substrate assembly using the pad and the CMP solution.

A method of modifying a surface of a semiconductor wafer is disclosed in U.S. Pat. No. 6,234,875 B1, and comprises:

(a) contacting the surface to be modified with a working surface of an abrasive article, the working surface comprising a phase separated polymer having a first phase and a second phase, the first phase being harder than the second phase; and

(b) relatively moving the surface to be modified and the abrasive article to remove material from the surface to be modified in the absence of an abrasive slurry.

In the integration schemes of existing methods for reducing surface irregularities in manufacturing semiconductor wafers, there is a need for: process simplification and cost reduction; improvement in the process for obtaining uniformity; preventing metal line damage due to CMP; and elimination of CMP “send aheads.”

### SUMMARY OF THE INVENTION

One object of the present invention is to provide, in an integration scheme for metal gap fill when making semiconductor wafers, process simplification and cost reduction.

Another object of the present invention is to provide, in an integration scheme for metal gap fill during semiconductor wafer manufacturing, an improvement of process uniformity.

A further object of the present invention is to provide, in an integration scheme for metal gap fill during manufacture of a semiconductor wafer, prevention of metal line damage due to CMP.

An object further still of the present invention is to provide, in an integration scheme for metal gap fill during manufacture of a semiconductor wafer, means for elimination of CMP “send aheads”.

In general, the invention integration scheme for metal gap fill using fixed abrasive CMP is accomplished by: filling gaps between metal lines on a semiconductor chip with a high density plasma (HDP) so that the bottom of the roofs is the desired interlayer dielectric (ILD) thickness, thereby eliminating the need for depositing a silane oxide cap layer; lowering the overfill of the HDP process using FAP to the bottom of the roofs of the HDP above the metal lines that remain between the roofs by virtue of the fact that the FAP process polishes only the typography and automatically stops at the bottom of the roofs when the wafer is planarized.

### BRIEF DESCRIPTION OF THE DRAWING FIGURES

FIG. 1A is a schematic cross sectional view of a portion of a semiconductor wafer of a prior art, after HDP fill.

FIG. 1B is a schematic cross sectional view of a portion of a semiconductor wafer after the process integration scheme of the invention using an HDP metal gap fill so that the bottom of the roofs is the desired interlayer dielectric (ILD) thickness T.

FIG. 2A depicts a schematic cross sectional view of a portion of a semiconductor wafer of the prior art after HDP fill and silane capping.

FIG. 3A is a schematic cross sectional view of a portion of a semiconductor wafer of a prior art process, after HDP fill, silane capping and CMP.

FIG. 3B depicts a schematic cross sectional view of a portion of a semiconductor wafer after the invention process integration scheme, for HDP metal gap fill, in the absence of silane capping, and fixed abrasive CMP with automatic stop at the bottom of the roofs to the desired or predetermined interlayer dielectric (ILD) thickness T and where the topography is removed.

### DETAILED DESCRIPTION OF PREFERRED EMBODIMENT OF THE INVENTION

It is known that the fixed abrasive CMP process (FAP) makes it possible to polish only the topography of an oxide or metal layer, and that the process stops automatically when the topography is removed. The FAP process is characterized by the advantages of: improved uniformity; neglegible dishing and pattern erosion and an increased process window—all of which makes endpoint detection unnecessary.

In the case of borophosphosilicate glass (BPSG) polish the FAP process is further characterized by the benefits of a high selectivity between nitride and oxide since the nitride above the gate conductor will not be eroded and this will increase the process window in terms of shorts for the CB etch. Furthermore, FAP will not dish in the oxide spacers, thereby avoiding topological problems.

In the case of a ILD polish using the FAP process, the benefits for ILD polish is that, high aspect ratio metal (e.g. Al) lines are filled with HDP and capped with a silane oxide layer. The dielectric is then polished back to the desired ILD thickness. However, this integration scheme has certain disadvantages in terms of uniformity. As a result the thickness, non-uniformity can affect further processing (e.g. the last metal via Al fill, which is very critical to the aspect ratio of the via).

On the other hand, the high density plasma-fixed abrasives CMP (FAP) integration scheme for the inter metal dielectrics of the invention process, is an integration scheme wherein the gaps between the metal lines are filled with HDP silane oxide or another (low k) insulating material which has been deposited so that the bottom of the roofs of the HDP is equal to the desired ILD thickness. The overfill of the HDP process is then lowered by FAP to the exact thickness of the ILD layer above the metal (e.g. Al) lines. The invention FAP process polishes only the topography above the exact or predetermined ILD layer thickness upon planarization. This leads to the absence of a need to deposit a silane oxide cap and to a reduced polishing time during FAP.

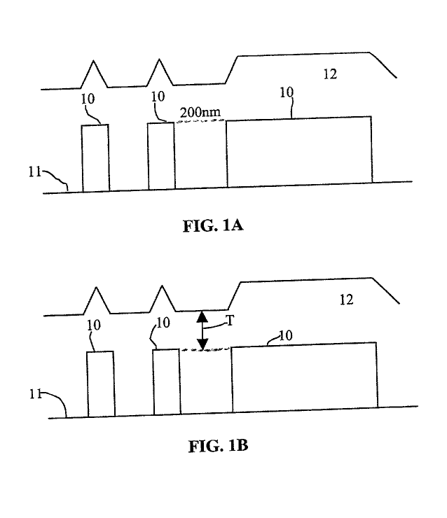

FIG. 1A depicts a simplified view of a schematic cross-section of a portion of a semiconductor wafer of the prior art, after HDP oxide fill. As may be seen, the metal interconnects 10 are made by first depositing a continuous layer of metal onto a substrate or dielectric layer 11, after which the metal is etched and the excess metal removed to form the desired pattern of metal interconnects 10. Thereafter, an insulating layer that is typically a HPD oxide 12 such as silicon dioxide or another (low k) insulating material is applied over each of the metal interconnects, and between the metal interconnects and over the top surface of a dielectric layer 11. However, before any additional layer of circuitry is applied via a photolithography process, it is usually desirable to treat the surface of the insulating layer to achieve a given degree of planarity. FIG. 1A shows a silicon dioxide layer is deposited on the HDP oxide and planarized by CMP. The desired ILD thickness is achieved by polishing the silane cap for a certain amount of time.

By contrast, when a high density plasma (HDP) chemical vapor deposition process of the invention is used to deposit an insulating layer over the top of the metal interconnects, between the metal interconnects and on the surface of the dielectric layer 11 so that the bottom of the roofs is the desired ILD thickness T, the use of fixed abrasive CMP processes (FAP) is able to affect planarity by polishing to remove topography of the semiconductor wafer with an automatic stop exactly at a predetermined endpoint or desired ILD thickness, without damage to the metal or Al lines, as shown in FIG. 1B.

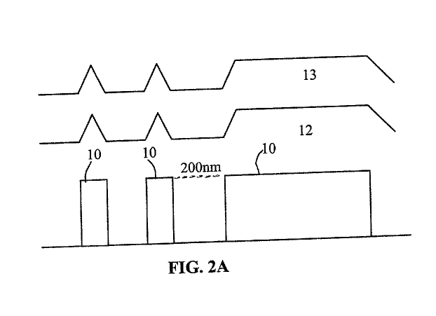

FIG. 2A depicts a schematic cross-sectional view of a portion of a semiconductor wafer of a prior art HDP fill after silane capping. The silane cap 13 on top of the HDP 12 evidences that the overfill of HDP, after the silane cap could be lowered to about 200 nm after CMP above the metal or Al lines remaining between the roofs of the HDP.

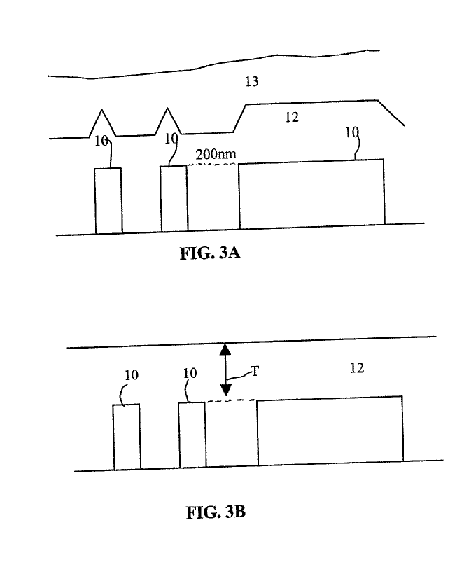

FIG. 3A shows a schematic cross-sectional view of a portion of a semiconductor wafer of a prior art process after chemical mechanical polishing (CMP). The overfill of the HDP upon polishing away the topography leaves about 200 nm of the HDP above the metal or Al lines between the roofs of the HDP.

From FIG. 3B, it can be seen that, upon subjecting the wafer with a HDP oxide fill so that the bottom of the roofs is the desired ILD thickness T, according to the invention, followed by fixed abrasive CMP to affect planarization of the topography, no silane cap layer need be deposited on the overfill.

In the context of the invention, a high density plasma (HDP) is one which fills entirely the volume it is in and is characterized by an average ionization density that is greater than 10¹¹ cm⁻³. A predetermined endpoint on the wafer sufficiently close above the metal interconnect lines, yet far enough away from the lines to prevent damage to the lines is determined by the level of the bottom of roofs above the metal lines.

A fixed abrasive polishing pad is one made from abrasive particles fixedly dispersed in a suspension medium and used in conjunction with planarizing solutions that do not contain an abrasive.

The advantages of the invention process integration scheme for HDP metal gap fill followed by fixed abrasive CMP provides: improved uniformity of the ILD thickness to avoid high flyers in contact resistance of via chains; prevention of metal line damage during CMP polish; cost reduction with throughput improvement [inclusive of shorter CMP time].

Further, after the gaps are filled the HDP process can be changed to a process with less Ar bombardment, which has the affect of increasing the deposition rate.

We claim:

1. In a method of planarizing a semiconductor wafer, the improvement comprising polishing above metal interconnect lines to uniformly polish the topography of the wafer to a predetermined endpoint on the wafer sufficiently close above the metal interconnect lines, yet far enough away from said lines to prevent damage to the lines, comprising:
a) filling gaps between metal interconnect lines of an inter metal dielectric in a wafer being formed, by depositing HDP fill on top of the metal interconnects, between the metal interconnects, and on the surface of a substrate or dielectric layer between said metal interconnects to create an HDP overfill so that the level of the bottom of roofs of the overfill above the metal lines is the endpoint upon use of FAP to remove topography;
b) contacting the surface of HDP overfill of the processed semiconductor wafer from step a) with a fixed abrasive polishing pad; and
c) relatively moving said wafer and said fixed abrasive polishing pad to affect a polishing rate sufficient to reach said predetermined endpoint and uniformly planar surface on the wafer sufficiently close above the metal interconnect lines and yet far enough away from said lines to prevent damage to said lines.

2. The method of claim 1 wherein said metal interconnect lines are selected from the group consisting of aluminum, titanium, copper, tungsten and mixtures thereof.

3. The method of claim 2 wherein said metal interconnect lines are aluminum.

4. The method of claim 2 wherein said metal interconnect lines are titanium.

5. The method of claim 2 wherein said metal interconnect lines are copper.

6. The method of claim 2 wherein said metal interconnect lines are tungsten.

7. The method of claim 3 wherein said predetermined endpoint on the wafer is about 50 nm.

8. The method of claim 4 wherein said predetermined endpoint on the wafer is about 50 nm.

9. The method of claim 5 wherein said predetermined endpoint on the wafer is about 50 nm.

10. The method of claim 6 wherein said predetermined endpoint on the wafer is about 50 nm.

11. The method of claim 3 wherein said predetermined endpoint on the wafer is less than 50 nm.

12. The method of claim 4 wherein said predetermined endpoint on the wafer is less than 50 nm.

13. The method of claim 5 wherein said predetermined endpoint on the wafer is less than 50 nm.

14. The method of claim 6 wherein said predetermined endpoint on the wafer is less than 50 nm.

15. A semiconductor wafer produced by the method of claim 1.
